(19) United States
(12) Patent Application Publication
(10) Pub. No.: US 2005/0004776 A1
(43) Pub. Date: Jan. 6, 2005

(54) Test process for memory card and test machine using the same

(75) Inventor: Chien-Yuan Chen, Banchiau City (TW)

Correspondence Address: TROXELL LAW OFFICE PLLC, SUITE 1404, 5205 LEESBURG PIKE, FALLS CHURCH, VA, 22041, US

(73) Assignee: Power Digital Card Co. Ltd.

(21) Appl. No.: 10/609,542

(22) Filed: Jul. 1, 2003

(51) Int. Cl. G06F 19/00; G01R 31/00

(52) U.S. Cl. 702/119

(57) ABSTRACT

The invention provides a test process for memory cards and a test machine using the same. The test machine includes a loading flatbed, a testing flatbed, a labeling flatbed, and an unloading flatbed. A half-finished memory card is forwarded to the loading flatbed before forwarding to the testing flatbed for testing, and then a qualified product is forwarded to the labeling flatbed whereas an unqualified product is delivered out of the testing flatbed. The half-finished memory card forwarded to the labeling flatbed is labeled and forwarded to the unloading flatbed whereby further delivering the tested memory card for subsequent packaging process. The labeling flatbed is a computerized engraving flatbed, which engraves related information of the memory card to a housing in order to save time and work needed for manually adhering stickers and misplacement of stickers, as well as to avoid abrasions, peeling off and illegitimate replacement of stickers.

### BACKGROUND OF THE INVENTION

(a) Field of the Invention

The invention relates to a test process for memory cards and a test machine using the same, and more particularly, to a test process for memory cards having related information engraved thereon using a computer, and a test machine using the same.

(b) Description of the Prior Art

Accompanied with approaching of the electronic era, mobility requirement of electronic data transmission gradually increases as well. Currently, new generation storage medium include flash drives, or referred to as smart cards and digital cards. These aforesaid devices are characterized by being small in size, and having large storage capacity and fast transmission rate, and are therefore especially suitable for multimedia storage and transmission. For that storage capacities of these memory cards vary according to different brands of manufacturers, it is necessary specify related information such as capacity, lot number, date code, company name of the memory cards thereon. Methods most commonly adopted for specifying the information are by means of printing or stickers. However, these methods are prone the following drawbacks:
1. Printed texts or texts on the stickers are likely to come off due to poor quality of printing or stickers, and thus leading to illegible labeling.
2. The stickers peel off easily in the presence of water or humid surroundings, and the information intended may become inaccessible.
3. Unmatched storage capacities are resulted from operation negligence namely adhering incorrect stickers. Potential confusions are arisen among consumers, sellers and industrialists.
4. It is rather uneconomical to invest human resources and time needed for subsequent adhering of stickers.
5. Replacement of stickers by certain unworthy sellers cannot be totally prevented, wherein stickers indicating higher capacities are used instead of stickers indicating actual capacities. Or, stickers indicating other manufacturers are stealthily exchanged instead of original manufactures. These phenomena incur deception on consumers.

### SUMMARY OF THE INVENTION

Therefore, in the view of the drawbacks of the prior art, the primary object of the invention is to provide a test process for memory cards. During the test process for memory cards, information including capacity, lot number, date code, and name of a memory card is directly engraved onto a housing of the memory card.

The secondary object of the invention is to provide a test process for memory cards, wherein capacity indication of a memory card is absolutely exempt from falling off by being directly engraved onto a housing of the memory card.

Another object of the invention is to provide a test process for memory cards capable of being work, and time efficient and offering complete accuracy by eliminating possible misplacing stickers during subsequent processes.

The other object of the invention is to provide a test process for memory cards having irreplaceable labels for ensuring rights of manufacturers and consumers.

### BRIEF DESCRIPTION OF THE DRAWINGS

FIG. 1 shows a schematic view of the operating machine according to the invention.

FIG. 2 shows a block diagram illustrating the manufacturing process according to the invention.

### DETAILED DESCRIPTION OF THE PREFERRED EMBODIMENTS

To better understand the characteristics, objects and functions of the invention, detailed descriptions shall be given with the accompanying drawings hereunder.

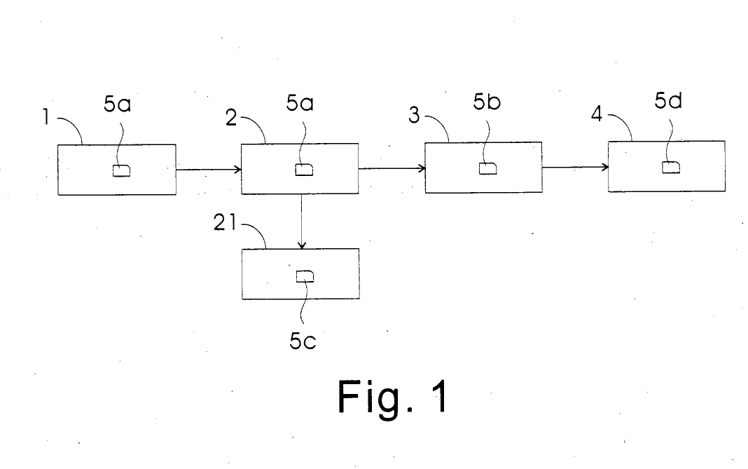

Referring to FIG. 1, a memory card test machine includes a loading flatbed 1, a testing flatbed 2, a labeling flatbed 3, and an unloading flatbed 4. The loading flatbed 1, the testing flatbed 2, the labeling flatbed 3, and the unloading flatbed 4 are either disposed on a machine for serial operations, or disposed independently; however, they are preferably disposed in series for serial operations in consideration time and work economic reasons. The loading flatbed 1 is for loading an untested and half-finished memory card 5a. The testing flatbed 2 is for testing the half-finished memory card 5a, and a qualified memory card 5b is forwarded to the labeling flatbed 3, or else an unqualified memory card 5c is delivered out of the testing flatbed 2 and gathered at an unqualified zone 21 for further inspection or invalidation. The labeling flatbed 3 is a laser engraving flatbed for engraving related information of the memory card including capacity, lot number, date code and name onto a housing of the qualified memory card 5b. The unloading flatbed 4 is for receiving a finished qualified memory card 5d, and for conveying the qualified memory card 5d out of the machine for subsequent packaging process.

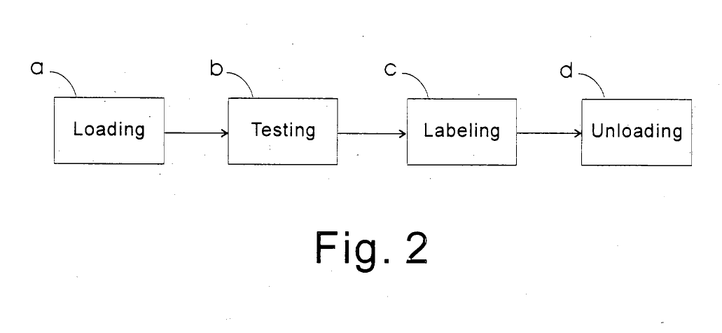

Referring to FIGS. 1 and 2, the invention comprises testing steps of:
a. loading: the half-finished memory card 5a is delivered to the loading flatbed 1, which then forwards the half-finished memory card 5a to the testing flatbed 2;
b. testing: the testing flatbed 2 tests the half-finished memory card 5a, and a qualified memory card 5b is forwarded to the labeling flatbed 3 whereas an unqualified memory card 5c is delivered out of the testing flatbed 2;
c. labeling: the labeling flatbed 3 engraves the qualified memory card 5b, and forwards the engraved and finished qualified memory card 5d to the unloading flatbed 4; and
d. unloading: the qualified memory card 5d forwarded to the unloading flatbed 4 is delivered out of the unloading flatbed 4 for subsequent packaging process.

Conclusive from the above, the invention is characterized by engraving related information of a memory card including capacity, lot number, date code and name onto the memory card, thereby saving time and work needed by sticker adhering manually carried out, and avoiding possible misplacement of the stickers. In addition, the invention is also capable of eliminating abrasions, peeling off or illegitimate replacement of the stickers.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A test process for memory cards comprising the steps of:
a. preparing a half-finished and untested memory card;
b. preparing a loading flatbed, a testing flatbed, a labeling flatbed, and an unloading flatbed;
c. loading the half-finished memory card to the loading flatbed, which then forwards the half-finished memory card to the testing flatbed;
d. testing the half-finished memory card using the testing flatbed, wherein a qualified product is forwarded to the labeling flatbed whereas an unqualified product is delivered out of the testing flatbed;
e. labeling the half-finished memory card forwarded to the labeling flatbed, which forwards the labeled memory card to the unloading flatbed; and
f. unloading and conveying the memory card forwarded to the unloading flatbed out of the unloading flatbed for subsequent packaging process.

2. The test process for memory cards in accordance with claim 1, wherein the labeling flatbed is an engraving flatbed.

3. The test process for memory cards in accordance with claim 2, wherein the engraving flatbed is a laser engraving flatbed.

4. The test process for memory cards in accordance with claim 2, wherein engraving contents set to the engraving flatbed are related information of the memory card including capacity, lot number, date code and name.

5. The test process for memory cards in accordance with claim 3, wherein engraving contents set to the engraving flatbed are related information of the memory card including capacity, lot number, date code and name.

6. The test process for memory cards in accordance with claim 1, wherein the loading flatbed, the testing flatbed, the labeling flatbed and the unloading flatbed are serially disposed on a machine for serial operations.

7. A test process for memory cards comprising the steps of:
a. preparing a half-finished and untested memory card;
b. preparing a test machine having a loading flatbed, a testing flatbed, a labeling flatbed, and an unloading flatbed;
c. loading the half-finished memory card to the loading flatbed, which then forwards the half-finished memory card to the testing flatbed;
d. testing the half-finished memory card using the testing flatbed, wherein a qualified product is forwarded to the labeling flatbed whereas an unqualified product is delivered out of the testing flatbed;
e. labeling the half-finished memory card forwarded to the labeling flatbed, which forwards the labeled memory card to the unloading flatbed; and
f. unloading and conveying the memory card forwarded to the unloading flatbed out of the unloading flatbed for subsequent packaging process.

8. The test process for memory cards in accordance with claim 6, wherein the labeling flatbed is an engraving flatbed.

9. The test process for memory cards in accordance with claim 7, wherein the engraving flatbed is a laser engraving flatbed.

10. The test process for memory cards in accordance with claim 8, wherein the engraving flatbed is a laser engraving flatbed.

11. The test process for memory cards in accordance with claim 7, wherein engraving contents set to the engraving flatbed are related information of the memory card including capacity, lot number, date code and name.

12. A test machine for memory cards comprising a loading flatbed, a testing flatbed, a labeling flatbed and an unloading flatbed; wherein:
a half-finished memory card is forwarded to the loading flatbed, which then forwards the half-finished memory card to the testing flatbed;
the half-finished memory card is tested by the testing flatbed, and a qualified product is forwarded to the labeling flatbed, whereas an unqualified product is delivered out of the testing flatbed;
the half-finished memory card forwarded to the labeling flatbed is labeled and forwarded to the unloading flatbed; and
the memory card forwarded to the unloading flatbed is delivered out of the machine for subsequent packaging process.

13. The test machine for memory cards in accordance with claim 10, wherein the labeling flatbed is an engraving flatbed.

14. The test machine for memory cards in accordance with claim 11, wherein the engraving flatbed is a laser engraving flatbed.

15. The test machine for memory cards in accordance with claim 11, engraving contents set to the engraving flatbed are related information of the memory card including capacity, lot number, date code and name.

16. The test machine for memory cards in accordance with claim 12, engraving contents set to the engraving flatbed are related information of the memory card including capacity, lot number, date code and name.
